(19) United States
(12) Patent Application Publication
(10) Pub. No.: US 2011/0057330 A1
(43) Pub. Date: Mar. 10, 2011

(54) ELECTRONIC DEVICE AND METHOD OF MANUFACTURING ELECTRONIC DEVICE

(75) Inventor: Yoshitaka USHIYAMA, Kanagawa (JP)

(73) Assignee: RENESAS ELECTRONICS CORPORATION, Kawasaki-shi (JP)

(21) Appl. No.: 12/876,371

(22) Filed: Sep. 7, 2010

(30) Foreign Application Priority Data
Sep. 8, 2009 (JP) 2009-207033

(51) Int. Cl. H01L 23/28; H01L 21/56

(52) U.S. Cl. 257/779; 438/126; 257/E21.502; 257/E23.16

(57) ABSTRACT

It is desired to provide an electronic device which can be easily taken out of a mold after a resin sealing processing. The electronic device include: an insulating layer; a wiring formed on the insulating layer; and a solder resist layer formed to cover the insulation layer and the wiring and including particles of an elastomer. An asperity is formed on a surface of the solder resist layer.

### INCORPORATION BY REFERENCE

This Patent Application is based on Japanese Patent Application No. 2009-207033. The disclosure of the Japanese Patent Application is incorporated herein by reference.

### BACKGROUND OF THE INVENTION

1. Field of the Invention

The present invention relates to an electronic device, and particularly to a solder resist of a wiring substrate.

2. Description of Related Art

In order to address an increase in the number of pins and signal transmission at higher speed, packages having area array-type terminals such as the BGA (Ball Grid Array) and the LGA (Land Grid Array) have been widely adopted for a semiconductor package. A manufacturing process of the area array-type semiconductor package includes a resin sealing step for protecting a semiconductor element. The resin sealing step includes steps of: enclosing a wiring substrate (semiconductor package substrate) that mounts a semiconductor element connected by means of a wire bonding connection or a flip chip connection thereon with molds; filling sealing resin liquefied at a high temperature into a cavity of the molds; and curing the filled sealing resin and taking a semiconductor device (semiconductor package) with the cured resin out of the molds. In the step of taking the semiconductor device out of the molds, various approaches have been considered to improve lowering of productivity due to adhesion of the semiconductor device to the molds.

A technique related to the step of taking a semiconductor device out of molds is disclosed in Japanese Patent Application Publication JP2002-166449A (which is referred to as Patent Document 1). A resin molding device disclosed in Patent Document 1 fills a resin into a cavity to perform resin molding and then, projects an ejector pin, to open the mold while releasing a molded piece from the cavity. Further, the resin molding device is provided with air suction means adapted to air-suck the molded piece onto a parting surface of the mold at mold opening. Such a resin molding device enables an automatic and smooth resin molding operation.

### SUMMARY

A solder resist layer having insulating properties is formed on a surface of a wiring substrate (package substrate, mounting board). The solder resist layer is formed for protecting a wiring pattern of the wiring substrate against external influences such as dusts and moisture and preventing solder from adhering to an unnecessary portion which may cause short-circuit. Further, the solder resist layer has an ability to bear a strain caused by thermal deformation. Especially when the solder resist layer is located at a connection part between a wiring substrate (package substrate) and a semiconductor element, the solder resist layer must have an ability to bear a strain caused by thermal deformation of the wiring substrate (package substrate) and the semiconductor element in the resin sealing step. Thus, the solder resist contains elastomer for relaxing an internal stress.

However, as a result of elaborate examination, the present inventor found a problem that, in addition to the difficulty of removing the base material of the sealing resin from the mold caused by its adhesion, the elastomer contained in the solder resist becomes softened and easily adheres to the molds due to heat generated in the resin sealing step, thereby making removal of the molded semiconductor device from the mold more difficult.

According to an aspect of the present invention, an electronic device includes: an insulating layer; a wiring formed on the insulating layer; and a solder resist layer formed to cover the insulation layer and the wiring and including particles of an elastomer. An asperity is formed on a surface of the solder resist layer.

According to another aspect of the present invention, a manufacturing method of an electronic device includes: forming a solder resist layer including particles of an elastomer to cover an insulating layer and a wiring formed on the insulating layer; mounting a semiconductor element on the solder resist layer; crimping a mold on a surface of the solder resist layer to cover the semiconductor element; sealing the semiconductor element by a resin by curing the resin after filling the resin into the gap between the semiconductor element and the mold; and taking the surface of the solder resist layer and the resin out of the mold after the sealing. An asperity is formed on the surface of the solder resist layer in the forming the solder resist layer.

In an electronic device of the present invention, since the solder resist is hard to adhere to a mold even when heat is applied, the solder resist can be easily taken out of the mold in a resin sealing step.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view of a semiconductor device 1 according to the present invention;

FIG. 2 is a sectional view showing a state in which a cavity formed by a mold 41 and a mold 42 is filled with a sealing resin 30 in a resin sealing step of the semiconductor device 1 of the present invention;

FIG. 3 is a partial sectional view of a wiring substrate 10 shown in FIG. 1 and FIG. 2;

FIG. 4 is an enlarged view of the portion A shown in FIG. 3;

FIG. 5 is a sectional view showing a state in which the wiring substrate 10 in FIG. 4 is in contact with the mold 41 in the resin sealing step;

FIG. 6 is a flow chart showing a method of manufacturing the wiring substrate 10 according to a first embodiment of the present invention;

FIG. 7 is a partial sectional view of the wiring substrate 10 shown in FIGS. 1 and 2 according to a second embodiment of the present invention;

FIG. 8 is an enlarged view of the portion B in FIG. 7;

FIG. 9 is a sectional view showing a state in which the wiring substrate 10 shown in FIG. 8 is in contact with the mold 41 in the resin sealing step;

FIG. 10 is a flow chart showing a method of manufacturing the wiring substrate 10 according to the second embodiment of the present invention;

FIG. 11 is a partial sectional view of a film 50 including a solder resist layer 52;

FIG. 12 is a flow chart showing a method of manufacturing the wiring substrate 10 according to a third embodiment of the present invention;

FIG. 13A is a sectional view showing the method of manufacturing the wiring substrate 10 according to the third embodiment of the present invention;

FIG. 13B is a sectional view showing the method of manufacturing the wiring substrate 10 according to the third embodiment of the present invention;

FIG. 14 is a sectional view of a semiconductor device 100 according to a fourth embodiment; and

FIG. 15 is a partial enlarged view of a mounting board 110 shown in FIG. 14.

### DESCRIPTION OF THE PREFERRED EMBODIMENTS

An electronic device according to some exemplary embodiments of the present invention will be described below referring to the accompanying drawings. The electronic device in the described embodiments represents a wiring substrate (package substrate, mounting board) or a semiconductor device in which a semiconductor element is mounted on the wiring substrate (package substrate, mounting board).

### First Embodiment

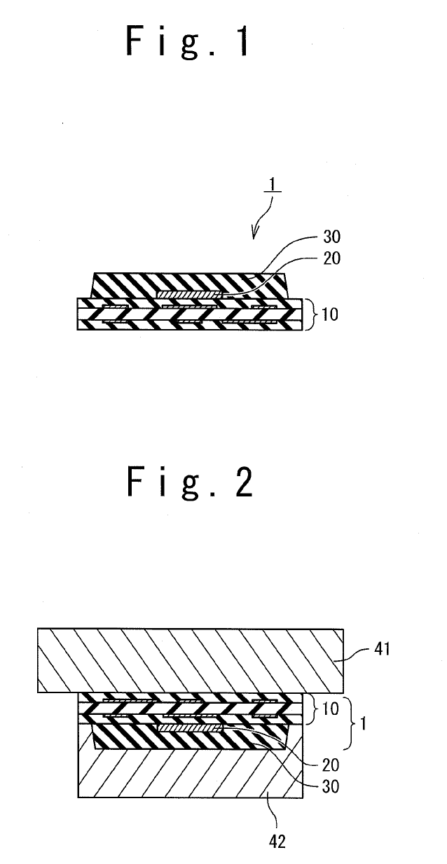

A first embodiment of the present invention will be described. FIG. 1 is a sectional view of a semiconductor device 1 according to the present embodiment. Referring to FIG. 1, the semiconductor device 1 includes a wiring substrate 10, a semiconductor element 20 and a sealing resin 30.

The wiring substrate 10 is an area array-type package substrate and connects the semiconductor element 20 to the mounting board exemplified by a printed wiring board (not shown). The semiconductor element 20 has a wiring for performing various functions and is connected to the wiring substrate 10. The method of connecting the semiconductor element 20 to the wiring substrate 10 may be either wire bonding (not shown) or flip chip connection (not shown). The sealing resin 30 covers the semiconductor element 20 for protection.

FIG. 2 is a sectional view showing a state in which a cavity formed by a mold 41 and a mold 42 is filled with the sealing resin 30 in a resin sealing step of the semiconductor device 1 of the present embodiment. Referring to FIG. 2, the resin sealing step will be described. The mold 41 and the mold 42 enclose the wiring substrate 10 that mounts the semiconductor element 20 thereon to form the cavity filled with the sealing resin 30. The sealing resin 30 in a form of high-temperature liquid is filled into the cavity formed by the mold 41 and the mold 42. The sealing resin 30 is not necessarily in the liquid form and may be in any state as long as it has fluidity (for example, in a gum state). Hereinafter, the liquid sealing resin 30 will be described. Since the mold 41 and the mold 42 are heated to about 150 to 200° C., the sealing resin 30 filled in the cavity becomes cured (FIG. 2). The semiconductor device 1 including the cured sealing resin 30 is taken out of the mold 41 and the mold 42. In a step of taking the semiconductor device 1 out of the mold 41 and the mold 42, disadvantageously, it is hard to strip the wiring substrate 10 away from the mold 41 and the mold 42. However, because the wiring substrate 10 of the present embodiment is hard to adhere to the mold 41 and the mold 42 as described later, the semiconductor device 1 can be easily taken out. The sealing resin 30 can be removed from the mold 41 and the mold 42 according to well known techniques. Details of the wiring substrate 10 will be described below.

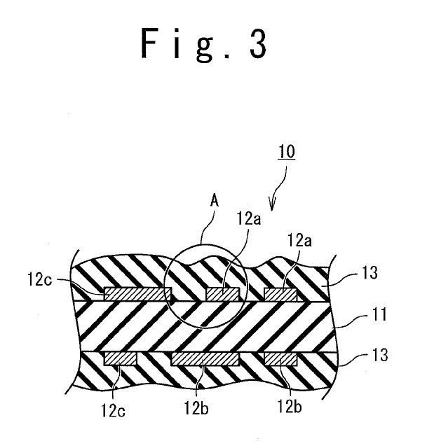

FIG. 3 is a partial sectional view of the wiring substrate 10 shown in FIGS. 1 and 2. Referring to FIG. 3, the wiring substrate 10 according to the first embodiment of the present invention includes an insulating layer 11, a wiring 12a, a wiring 12b, a wiring 12c and a solder resist layer 13. A resist material forming the solder resist layer 13 is described as a “solder resist”, not a “solder resist layer”. The wiring substrate 10 may be configured by forming a first solder resist 13 and a second solder resist 14 on a multi-layer substrate obtained by laminating one or more insulating layers and one or more wirings on the wiring 12a or the wiring 12b. Alternatively, the wiring substrate 10 may be configured by forming the first solder resist 13 and the second solder resist 14 on the insulating layer, only one surface of which has the wirings thereon. Alternatively, a wiring (not shown) other than the wirings 12a, 12b and 12c may be formed on the insulating layer 11. A part of the solder resist layer 13 is opened so as to expose parts of the wirings 12a, 12b, thereby forming electrode pads (not shown). A wiring is wire bonding connected or a solder ball is flip chip connected to each of the electrode pads on one wiring layer side to which the semiconductor element 20 is connected. An external terminal such as a solder ball is connected to the electrode pad on the other wiring layer side.

The insulating layer 11 is a base member on which the wiring 12a, the wiring 12b and the wiring 12c are formed and blocks electrical conduction to the wiring 12a, the wiring 12b and the wiring 12c. The insulating layer 11 can be formed of a glass epoxy resin substrate obtained by impregnating a cloth woven from glass fibers with epoxy resin, a glass composite substrate obtained by impregnating glass fibers formed into a mat shape obtained by trimming the glass fibers with epoxy resin or the like according to well known techniques. A wiring layer (not shown) other than the wirings 12a and 12b may be formed in the insulating layer 11. A through hole penetrating the insulating layer 11 may be formed to connect predetermined wirings included in the wirings 12a, 12b to each other.

The wiring 12a is a leading wiring formed on the insulating layer 11 with a predetermined pattern. The wiring 12b is a leading wiring formed with a predetermined pattern on a surface of the insulating layer 11 opposite to a surface on which the wiring 12a is formed. The wiring 12a and the wiring 12b can be formed according to well known techniques. The thickness of each of the wiring 12a and the wiring 12b is, for example, in the range of 10 to 35 μm. The patterns of the wiring 12a and the wiring 12b can form an asperity (regular or irregular pattern of height in the direction of thickness, namely, a lot of depressions and projections formed on the surface) on a surface of the solder resist layer 13. Details of formation of the asperity on the solder resist layer 13 will be described later.

The wiring 12c may be formed in addition to the wiring 12a and the wiring 12b. The wiring 12c is a dummy wiring electrically isolated from other circuits and formed on a surface of the insulating layer 11 where the wiring 12a and the wiring 12b are not formed by using the same material as those of the wiring 12a and the wiring 12b in a similar manner to form asperity on the surface of the solder resist layer 13. Accordingly, the wiring 12c need not be electrically connected to the semiconductor element 20. The wiring 12c is formed on the surface of the insulating layer 11 in any shape such as dot or mesh and its thickness is the same as that of the wiring 12a and the wiring 12b.

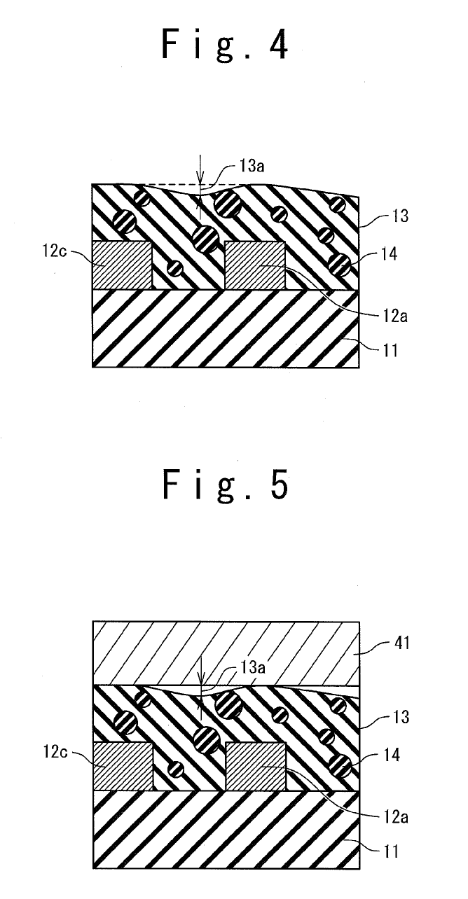

Details of the solder resist layer 13 will be described. FIG. 4 is an enlarged view of the portion A shown in FIG. 3. The solder resist layer 13 is an insulating film formed so as to cover the insulating layer 11, the wiring 12a, the wiring 12b and the wiring 12c to protect the wiring 12a, the wiring 12b and the wiring 12c. The solder resist layer 13 prevents contact of the wiring 12a, the wiring 12b and the wiring 12c with one another as well as prevents short-circuit caused by adhesion of the solder formed on the wiring substrate 10 to any part other than the electrode pads provided for electrical connection. The minimum film thickness of the solder resist layer 13 is a thickness that can cover the wiring 12a, the wiring 12b and the wiring 12c and the maximum film thickness of the solder resist layer 13 is a thickness that does not cause a crack due to strain at manufacturing and usage of the semiconductor device 1. The film thickness of the solder resist layer 13 is, for example, in a range of 25 to 70 μm. The solder resist layer 13 is opened so as to expose parts of the wirings 12a, 12b and 12c. An electrode pad is formed on each opening and a wiring is wire bonding connected or a solder ball is connected thereto.

The solder resist layer 13 includes elastomer 14 for relaxing an internal stress. The elastomer 14 is a polymer with an average particle size of 5 to 15 μm that disperses in the solder resist layer 13. The elastomer 14 has a glass transition point that is equal to or lower than a temperature for curing the sealing resin 30 (for example, not higher than 150° C.), is softened at a temperature that is equal to or higher than the glass transition point and expresses adhesiveness. Since the solder resist layer 13 has a section located between the wiring substrate 10 and the semiconductor element 20, the solder resist layer 13 needs to have an ability to bear the strain caused by thermal deformation of the wiring substrate 10 and the semiconductor element 20 in the resin sealing step. The elastomer 14 acts to relax the internal stress caused by the deformation and prevent occurrence of the crack on the solder resist layer 13 and removal of the solder resist layer 13 from the insulating layer 11. However, the elastomer 14 is softened at the glass transition point or higher and thus, is easy to adhere to the other members. Consequently, the elastomer 14 exposed from the surface of the solder resist layer 13 becomes hard to be removed when contacting the mold 41 and the mold 42 in the resin sealing step, thereby contributing to lowering of manufacturing efficiency. A composition of the solder resist layer 13 and the elastomer 14 may be the composition of well known solder resists and elastomer.

The solder resist layer 13 has an asperity on its surface. The insulating layer 11 is positioned below depressions of the surface asperity of the solder resist layer 13. The wiring 12a, the wiring 12b and the wiring 12c exist below the projections of the surface asperity of the solder resist layer 13. That is, the solder resist layer is formed on the insulating layer 11 so that an asperity that reflect the asperity formed of regions where the wirings 12a, 12b, 12c exist and regions where the wirings 12a, 12b, 12c do not exist are formed on the solder resist layer 13. In other words, it is necessary to apply the solder resist over the insulating layer 11 and the wirings 12a, 12b, 12c so as not to make the surface of the solder resist flat. Such structure can be achieved, for example, by increasing viscosity of the solder resist or decreasing an amount of applied solder resist to decrease the thickness of the solder resist layer. When the thickness of the solder resist layer is decreased, influence of the asperity of the wirings becomes more prominent and thus, the asperity on the surface of the solder resist layer 13 becomes grooved to be a groove shape. For achieving such a structure, the film thickness of the solder resist is determined such that the asperity is formed corresponding to the level difference between the region where the wiring is arranged and the region where the wiring is not arranged by applying the solder resist on the insulating layer.

The asperity on the surface of the solder resist layer 13 can decrease contact areas between the solder resist layer 13 and the mold 41, and the mold 42 in the resin sealing step. That is, the surface area of the elastomer 14 that is exposed from the surface of the solder resist layer 13 and contacts the mold 41 and the mold 42 can be decreased. Therefore, although the solder resist layer 13 includes the elastomer 14 as an adhesive component, since the surface area of the elastomer 14 that contacts the mold 41 and the mold 42 is small, the adhesive strength of this solder resist to the mold 41 and the mold 42 is smaller than that of the solder resist including the elastomer 14 without asperity (not shown). In other words, the solder resist layer 13 of the wiring substrate 10 according to the present embodiment is advantageously easy to be removed from the mold 41 and the mold 42.

FIG. 5 is a sectional view showing a state in which the wiring substrate 10 in FIG. 4 is in contact with the mold 41 in the resin sealing step. Referring to FIG. 5, depressions of the surface of the solder resist layer 13 are not in contact with the mold 41. Consequently, the surface area of the elastomer 14 that contacts the mold 41 is decreased due to the asperity on the surface of the solder resist layer 13. Therefore, in the wiring substrate 10 of present embodiment, since the solder resist layer 13 can be easily removed from the mold 41 and the mold 42, the manufacturing efficiency of the semiconductor device 1 can be improved. It is preferred that a height 13a of the asperity on the solder resist layer 13 is equal to or smaller than 5 μm. By setting the height 13a to be 5 μm or less, the liquid sealing resin 30 in the resin sealing step can be prevented from leaking from gaps between the asperity of the solder resist layer 13, and the mold 41 and the mold 42 (refer to FIG. 2).

It is preferred that the width of each of the wirings 12a, 12b and 12c is equal to or larger than the average particle size (the average of the radius of the particles) of the elastomer 14. When the wiring width is smaller than the average particle size of the elastomer 14, if the elastomer 14 exists on the wiring, the elastomer 14 does not fall in projections of the solder resist 13 formed on the wiring and thus, the surface of the elastomer 14 cannot be sufficiently covered with a base material which is a resin component of the solder resist 13.

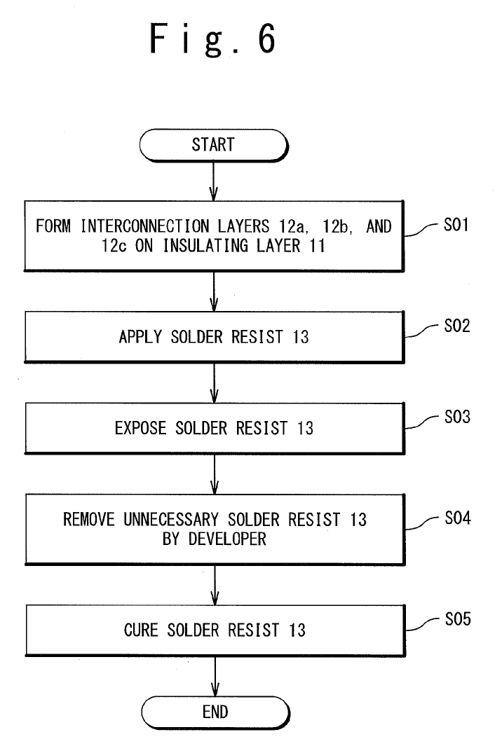

FIG. 6 is a flow chart showing a method of manufacturing the wiring substrate 10 according to the first embodiment of the present invention. Referring to FIG. 6, a method of manufacturing the wiring substrate 10 according to the first embodiment of the present invention will be described.

The wiring is formed on the insulating layer before the solder resist layer is formed. Namely, the wiring 12a and the wiring 12b are formed on the insulating layer 11, such as a glass epoxy substrate or a glass composite substrate, having insulating properties. The wiring 12c is simultaneously formed on a section where the wiring 12a and the wiring 12b are not formed to form asperity on the surface of the solder resist layer 13. The wiring 12a, the wiring 12b and the wiring 12c can be formed according to well known techniques of forming a wiring pattern, such as etching (Step S01). The insulating layer on which the wiring is formed may be provided in some other manner before the solder resist layer is formed.

The solder resist layer 13 including the elastomer 14 is applied on the insulating layer 11, the wiring 12a, the wiring 12b and the wiring 12c to make the surface of the resist layer 13 flat. Examples of an applying method include a spray method, a screen printing method, a roller coating method and a curtain coater method. The solder resist layer 13 is applied so that the film thickness after curing is in the range of 25 to 70 μm. The solder resist layer 13 may be applied once or may be applied plural times. The applied solder resist layer 13 is prebaked by thermal treatment. For example, the applied solder resist layer 13 is prebaked under temperatures of 60 to 100° C. for 10 to 30 minutes (Step S02).

The solder resist layer 13 is exposed through a mask based on a resist pattern of the solder resist layer 13. The solder resist layer 13 is exposed to, for example, light exemplified by an ultraviolet light. The solder resist layer 13 is exposed so as to be drawn by a laser based on the predetermined resist pattern (Step S03). The solder resist layer 13 may be either a negative resist, solubility to a developer of which decreases when exposed, resulting in that an exposed portion remains after development, or a positive resist, solubility to a developer of which increases when exposed, resulting in that the exposed portion is removed.

Unnecessary portions of the exposed solder resist layer 13 are eliminated by the developer (Step S04).

The solder resist layer 13 is further cured by heating and ultraviolet irradiation. As an example of a heating method, the solder resist layer 13 is heated under 100 to 200° C. for 30 to 60 minutes. The solder resist layer 13 is cured by only heating, by only ultraviolet irradiation or by combination of heating and ultraviolet irradiation depending on a solder resist material. In the method using the combination of heating and ultraviolet irradiation, for example, the solder resist layer is cured by irradiating ultraviolet rays after heating. Whereby, even if an uncured portion remains in the solder resist after heating, the solder resist can be completely cured by subsequent ultraviolet irradiation. The solder resist layer 13 applied on a section where the wiring 12a, the wiring 12b and the wiring 12c are formed and the solder resist layer 13 applied on the insulating layer 11 both have smooth surfaces after the application in Step S02 but differ from each other in film thickness after the application, and in turn, the film thickness after curing differs based on vaporization of a solvent in the composition and shrinkage on curing of resin. Therefore, an asperity is formed on the surface of the solder resist layer 13 during curing. The insulating layer 11 exists below depressions of the solder resist layer 13 and the wiring 12a, the wiring 12b and the wiring 12c exist below projections of the solder resist layer 13 (Step S05).

A manufacturing process by which the wiring substrate 10 manufactured according to the flow chart in FIG. 6 becomes the semiconductor device 1 will be described referring to FIG. 2. The semiconductor element 20 is mounted onto the solder resist layer 13 of the wiring substrate 10 formed according to the flow chart in FIG. 6. The semiconductor element 20 is connected to the wiring substrate by wire bonding connection or flip chip connection. The mold 41 and the mold 42 enclose the wiring substrate 10 on which the semiconductor element 20 is mounted to form a cavity to be filled with the sealing resin 30. At this time, as shown in FIG. 2, the mold 41 and the mold 42 each are crimped onto the surface of the solder resist layer 13.

The sealing resin 30 in a high-temperature fluid state is filled into the cavity formed by the mold 41 and the mold 42. The mold 41 and the mold 42 are heated to about 150 to 200° C., thereby curing the sealing resin 30 filled in the cavity (FIG. 2). The semiconductor device 1 including the cured sealing resin 30 is taken out of the mold 41 and the mold 42. In the step of taking the semiconductor device 1 out of the mold 41 and the mold 42, according to the present embodiment, since the solder resist layer 13 of the wiring substrate 10 is hard to adhere to the mold 41 and the mold 42, the semiconductor device 1 can be easily pulled out. The above-mentioned steps of mounting the semiconductor element on the wiring substrate 10, cramping the molds, filling resin and then curing the filled resin and taking the wiring substrate 10 out of the molds are similar to steps in a second embodiment and a third embodiment described later.

In the wiring substrate 10 in the first embodiment of the present invention, since the solder resist layer 13 has an asperity on its surface, the surface area of the elastomer 14 that contacts the mold 41 and the mold 42 in the resin sealing step can be decreased. An adhesive strength of the wiring substrate 10 to the molds 41, 42 is smaller than that of the solder resist without asperity on the surface thereof and thus, the semiconductor device 1 can be easily taken out of the mold 41 and the mold 42 after the resin sealing step. Therefore, the wiring substrate 10 of the present embodiment can be removed from the mold 41 and the mold 42 without spending much time, the amount of the elastomer 14 adhered to the mold 41 and the mold 42 is small and cleaning of the mold 41 and the mold 42 does not take so much time. For these reasons, the manufacturing efficiency of the semiconductor device 1 can be improved. Further, dirt are hard to adhere to the mold 41 and the mold 42, dirt can be prevented from transferring from the mold 41 and the mold 42 to the wiring substrate 10 and an assembly failure that the wiring substrate 10 is not attached to the solder ball can be also prevented. In addition, since the wiring substrate 10 of the present embodiment can be easily removed from the mold 41 and the mold 42, static electricity can be prevented from occurring at removal, thereby avoiding a functional failure of the semiconductor device 1 (semiconductor element 20).

### Second Embodiment

A second embodiment of the present invention will be described. In the second embodiment of the present invention, a step of intentionally forming an asperity on the surface of a solder resist layer 15. Since the other configuration is the same as that in the first embodiment, the same reference numerals are given to the same components and redundant description is omitted.

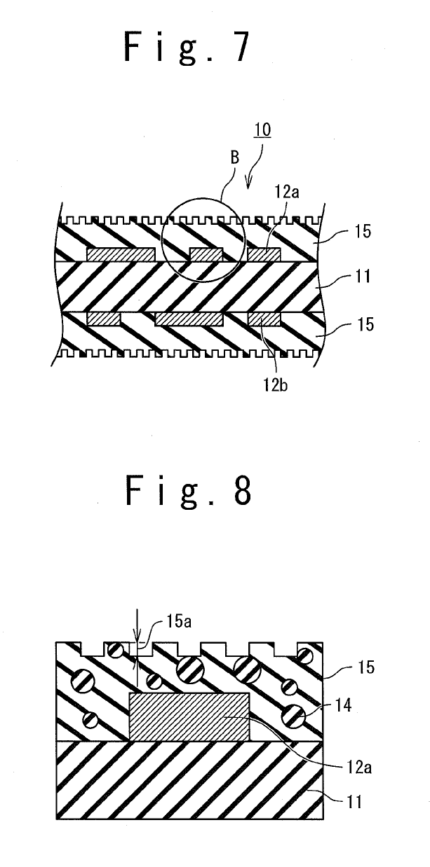

FIG. 7 is a partial sectional view of the wiring substrate 10 shown in FIGS. 1 and 2 according to the second embodiment of the present invention. Referring to FIG. 7, the wiring substrate 10 in the second embodiment of the present invention includes an insulating layer 11, a wiring 12a, a wiring 12b and a solder resist layer 15. The insulating layer 11, the wiring 12a and the wiring 12b are the same as those in the first embodiment. As in the first embodiment, the dummy wiring 12c may be formed on the insulating layer 11.

Details of the solder resist layer 15 will be described. FIG. 8 is an enlarged view of the portion B in FIG. 7. The solder resist layer 15 includes the elastomer 14. The solder resist layer 15 is the same as the solder resist layer 13 in the first embodiment except for the shape of the surface thereof. Accordingly, composition of the solder resist layer 15 may be the same as that of the solder resist layer 13 and may be composition of well-known solder resists.

The solder resist layer 15 has an asperity on its surface. The asperity on the surface of the solder resist layer 15 has similar effects to those attained by the asperity on the surface of the solder resist layer 13. In other words, the asperity on the surface of the solder resist layer 15 can decrease contact areas between the solder resist layer 15 and the molds 41, 42 in the resin sealing step. Further, the asperity on the surface of the solder resist layer 15 can be exposed from the surface of the solder resist layer 15, thereby decreasing a surface area of the elastomer 14 that contacts the mold 41 and the mold 42. Thus, although the solder resist layer 15 includes the elastomer 14 as an adhesive component, since the surface area of the elastomer 14 that contacts the mold 41 and the mold 42 is small, the adhesive strength of the solder resist layer 15 to the mold 41 and the mold 42 is smaller than the solder resist (not shown) without asperity including the elastomer 14. That is, like the solder resist layer 13 in the first embodiment, the solder resist layer 15 of the wiring substrate 10 of the present embodiment also has the effect that it can be easily removed from the mold 41 and the mold 42.

It is preferred that a height 15a of the asperity on the surface of the solder resist layer 15 is equal to or smaller than 5 μm. When the height 15a is 5 μm or less, the fluidic sealing resin 30 in the resin sealing step can be prevented from leaking from between the asperity on the surface of the solder resist layer 15 and the molds 41, mold 42 (refer to FIG. 2). The asperity on the surface of the solder resist layer 15 can be formed by laser or abrasive grains after the solder resist layer 15 is cured. The method of forming by means of laser is preferable because spacing and size of each asperity on the surface of the solder resist layer 15 can be adjusted more finely than the asperity on the solder resist layer 13 in the first embodiment. An example of the method of forming by use of abrasive grains is to form asperity on the surface by using an abrasive containing abrasive grains. The method is not limited to the laser or abrasive grain method as long as the asperity is formed on the surface of the solder resist layer 15.

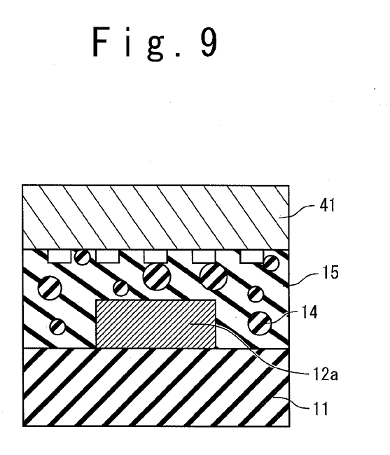

FIG. 9 is a sectional view showing a state in which the wiring substrate 10 shown in FIG. 8 is in contact with the mold 41 in the resin sealing step. Referring to FIG. 9, depressions on the surface of the solder resist layer 15 are not in contact with the mold 41. The asperity on the surface of the solder resist layer 15 decrease the surface area of the elastomer 14 that contacts the mold 41. Consequently, as in the wiring substrate 10 in the first embodiment, in the wiring substrate 10 in the second embodiment of the present invention, since the solder resist layer 15 can be easily removed from the mold 41 and the mold 42, the manufacturing efficiency of the semiconductor device 1 can be improved.

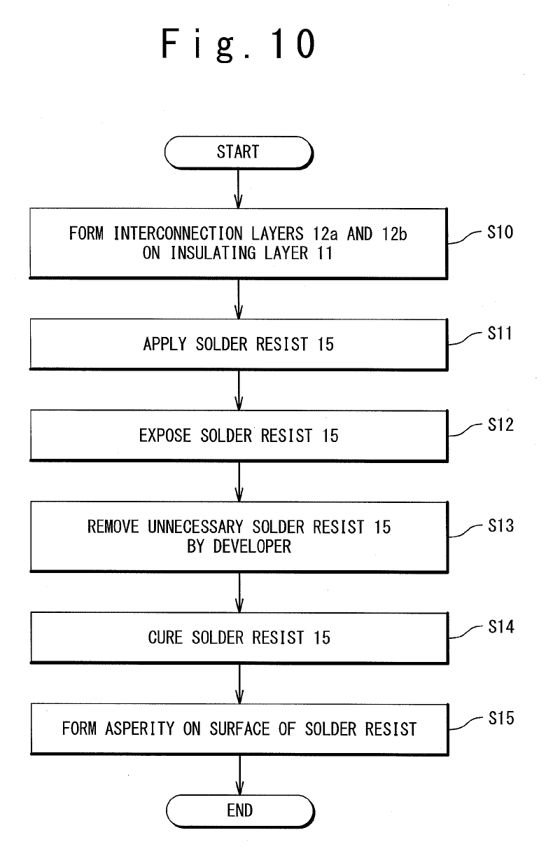

FIG. 10 is a flow chart showing a method of manufacturing the wiring substrate 10 according to the second embodiment of the present invention. Referring to FIG. 10, the method of manufacturing the wiring substrate 10 in the second embodiment of the present invention will be described.

The wiring 12a and the wiring 12b are formed on the insulating layer 11 such as a glass epoxy substrate or a glass composite substrate that has insulating properties. The wiring 12a and the wiring 12b can be formed according to well known wiring pattern forming techniques such as etching (Step S10).

The solder resist layer 15 including the elastomer 14 may be applied on the insulating layer 11, the wiring 12a and the wiring 12b so that its surface is made flat. Applying methods include a spray method, a screen method, a roller coating method and a curtain coater method. The solder resist layer 15 is applied so as to have a film thickness after curing of 25 to 70 μm. The applied solder resist layer 15 is dried by heat treatment. For example, the applied solder resist layer 15 is dried under 60 to 100° C. for 10 to 30 minutes (Step S11).

The solder resist layer 15 is exposed based on a resist pattern by light containing ultraviolet rays through a mask or as drawn by laser (Step S12). The solder resist layer 15 may be either a negative type or a positive type.

An unnecessary portion of the exposed solder resist layer 15 is removed by use of a developer (Step S13). Thereby, electrode pads which are flip chip connected or wire bonding connected and formed of parts of the wirings 12a, 12b are formed.

The solder resist layer 15 is cured by further applying at least either heating or ultraviolet irradiation. For example, the solder resist layer 15 is heated under 100 to 200° C. for 30 to 60 minutes (Step S14).

Asperity having the height 15a of 5 μm or less in the thickness direction is formed on the cured solder resist layer 15 by laser irradiation or abrasive grains (Step S15).

Since manufacturing process by which the wiring substrate 10 manufactured according to the flow chart in FIG. 10 becomes the semiconductor device 1 is the same as that in the first embodiment, description thereof is omitted.

In the wiring substrate 10 in the second embodiment of the present invention, since the solder resist layer 15 has an asperity on its surface, the surface area of the elastomer 14 that contacts mold 41 and the mold 42 in the resin sealing step can be decreased. Consequently, the wiring substrate 10 in the second embodiment of the present invention has a similar effect to that of the wiring substrate 10 in the first embodiment. In the wiring substrate 10 in the second embodiment of the present invention, spacing and size of each of the depressions (recession) and projections (protrusion) forming the asperity on the surface of the solder resist layer 15 can be adjusted more finely than the asperity on the solder resist layer 13 in the first embodiment by use of laser. According to the present embodiment, the first embodiment can be combined with the second embodiment. In other words, the asperity may be formed on the surface of the wiring substrate 10 in the first embodiment according to the step of forming the asperity in the second embodiment.

### Third Embodiment

A third embodiment will be described. The third embodiment of the present invention is obtained by changing the solder resist layer 15 in the second embodiment to a solder resist as a dry film. Thus, the same reference numerals are given to the same components as those in the second embodiment and thus, redundant description is omitted.

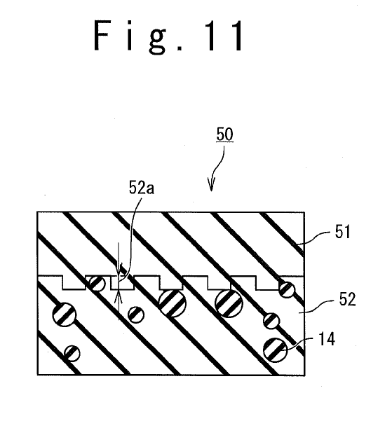

FIG. 11 is a partial sectional view of a film 50 including a solder resist layer 52. The film 50 is used to cover the insulating layer 11 and the wirings 12a, 12b provided on the insulating layer 11 with the solder resist layer 52 of the dry film. Referring to FIG. 11, the film 50 includes a support film 51 and the solder resist layer 52.

The support film 51 adheres to the solder resist layer 52 to support the solder resist layer 52. The support film 51 has an asperity on its surface adhered to the solder resist layer 52. Since the support film 51 has the asperity, the shape corresponding to the asperity of the support film 51 is transferred to the surface of the solder resist layer 52 adhered to the support film 51. After the solder resist layer 52 is adhered to cover the insulating layer 11, the wiring 12a and the wiring 12b, the support film 51 is removed from the solder resist layer 52. The support film 51 may be made of a well known material having a function of supporting the solder resist layer 52 of dry film-type.

The solder resist layer 52 is adhered so as to cover the insulating layer 11, the wiring 12a and the wiring 12b to protect them. The solder resist layer 52 is different from the solder resist layer 15 in the second embodiment in that it does not require a drying step after being adhered so as to cover the insulating layer 11, the wiring 12a and the wiring 12b. However, after complete curing, the solder resist layer 52 has the same performance as the solder resist layer 15. Therefore, a composition of the cured solder resist layer 52 is the same as that of the solder resist layer 15 and includes the elastomer 14.

The solder resist layer 52 has an asperity corresponding to the asperity of the support film 51. When the solder resist layer 52 is adhered to the insulating layer 11, the wiring 12a and the wiring 12b, the asperity is located on a surface of the solder resist layer 52. The asperity on the surface of the solder resist layer 52 can produce similar effects as the asperity of the solder resist layer 15. That is, the asperity on the surface of the solder resist layer 52 can reduce a contact area between solder resist layer 52 and the molds 41, 42 in a resin sealing step, and the asperity can be exposed from the surface of the solder resist layer 52, thereby decreasing a surface area of the elastomer 14 that contacts the mold 41 and the mold 42. It is preferred that the asperity of the solder resist layer 52, like the asperity of the solder resist layer 15, has a height 52a of 5 μm or less.

The film 50 may further include a protecting film for protecting its surface on a plane on which the asperity of the solder resist layer 52 are not formed (plane that is not in contact with the support film 51).

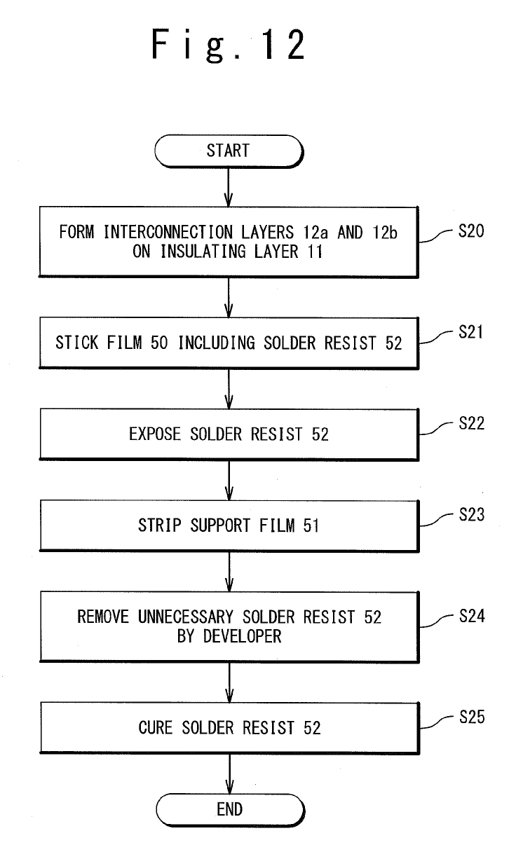

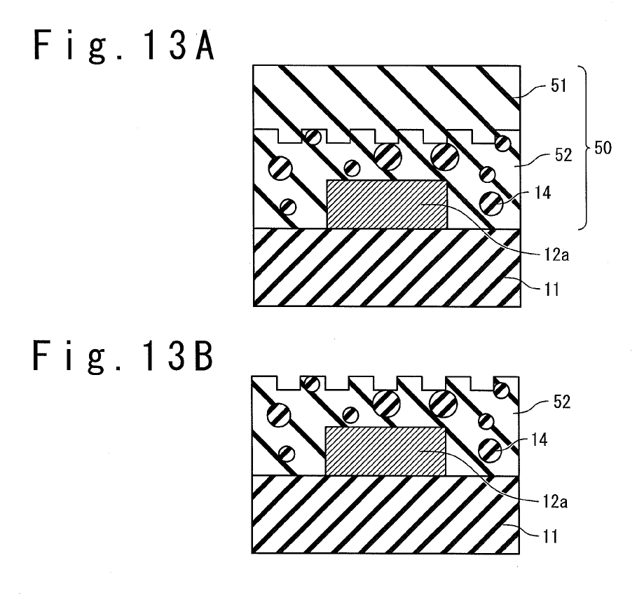

FIG. 12 is a flow chart showing a method of manufacturing the wiring substrate 10 according to the third embodiment of the present invention. FIG. 13 is a sectional view showing the method of manufacturing the wiring substrate 10 according to the third embodiment of the present invention. Referring to FIGS. 12 and 13, the method of manufacturing the wiring substrate 10 according to the third embodiment will be described.

The wiring 12a and the wiring 12b are formed on the insulating layer 11 such as a glass epoxy substrate or a glass composite substrate that has insulating properties. The wiring 12a and the wiring 12b can be formed according to well known wiring pattern forming techniques such as etching (Step S20).

The film 50 including the solder resist layer 52 supported by the support film 51 is stuck (adhered) so as to cover the insulating layer 11 and the wirings 12a, 12b provided on the insulating layer 11, placing the support film 51 as the surface side (the upper side when the side of the insulating layer 11 is supposed to be the lower side). The solder resist layer 52 includes particles of the elastomer 14. Any well known adhering methods such as thermo-compression boding can be adopted (Step S21, FIG. 13A).

The film 50 including the solder resist layer 52 is exposed based on a resist pattern of the solder resist layer 52 by light containing ultraviolet rays through a mask or as drawn by laser (Step S22). The solder resist layer 52 may be either a negative type or a positive type.

The support film 51 is stripped from the solder resist layer 52. The asperity is formed on the surface of the solder resist layer 52 in contact with the support film 51 (Step S23, FIG. 13B).

The exposed solder resist layer 52 is developed by using a developer to eliminate an unnecessary portion (Step S24). As a result, parts of the wirings 12a, 12b are exposed, thereby forming electrode pads.

The solder resist layer 52 is cured by further applying at least either heating or ultraviolet irradiation. For example, the solder resist layer 52 is heated under 100 to 200° C. for 30 to 60 minutes (Step S25).

A manufacturing process by which the wiring substrate 10 manufactured according to the flow chart in FIG. 12 becomes the semiconductor device 1 is the same as that in the first and second embodiments and thus, description thereof is omitted.

The semiconductor device 1 is manufactured by using the wiring substrate 10 according to any of the first to third embodiments of the present invention. Although the resin sealing step of the semiconductor device 1 has been described in this specification, the other steps relating to manufacturing of the semiconductor device 1 can be performed according to any method known to those skilled in the art.

### Fourth Embodiment

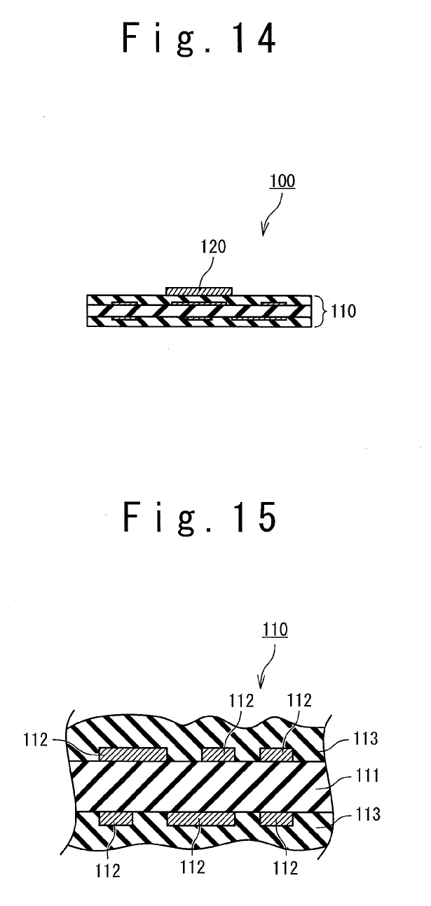

The wiring substrates 10 according to the first to third embodiments of the present invention can be applied to a mounting board. FIG. 14 is a sectional view of the semiconductor device 100 in a fourth embodiment. Referring to FIG. 14, the semiconductor device 100 includes a mounting board 110 and a semiconductor package 120.

FIG. 15 is a partial enlarged view of a mounting board 110 shown in FIG. 14. Referring to FIG. 15, the mounting board 110 includes the insulating layer 111, the wiring 112 and a solder resist layer 113. A configuration of each component of the mounting board 110 is similar to that of the wiring substrate 10. That is, the insulating layer 111 is similar to the insulating layer 11, the wiring 112 is similar to the wiring 12a and the wiring 12b, and the solder resist layer 113 is similar to the solder resist layer 13, the solder resist layer 15 or the solder resist layer 52.

Referring to FIG. 14, the semiconductor package 120 is a semiconductor package manufactured by a well known method, and the semiconductor devices 1 according to the first to third embodiments of the present invention are exemplified. The semiconductor device 100 can be manufactured by any method known to those skilled in the art. As described above, the electronic device of the present invention can be applied to various embodiments of the semiconductor device in which the semiconductor element is mounted on the wiring substrate (package substrate, mounting board) and the wiring substrate (package substrate, mounting board).

### Combinations of the Embodiments

Although the first to fourth embodiment have been described, the structure and the method of forming the asperity on the surface of the solder resist layer in the first embodiment can be combined with the structure and the method of forming the asperity on the surface of the solder resist layer in the second embodiment. With such combination, the asperity on the surface of the solder resist layer can be made larger, so that the surface of the solder resist layer becomes hard to adhere to the molds and thus, the semiconductor device can be taken out of the molds in the resin sealing step more easily. The structure and the method of forming the asperity on the surface of the solder resist layer, which generated by presence or absence of the wiring, in the first embodiment can be combined with the structure and the method of using the solder resist of dry film type in the third embodiment. For example, by forming a plurality of wirings and dummy wiring on the insulating layer and sticking the solder resist of dry film type on which the asperity are formed in the third embodiment thereonto, the asperity in the third embodiment in addition to the asperity in the first embodiment are formed on the surface of the solder resist. With such combination, the surface of the solder resist layer becomes harder to adhere to the molds and thus, the semiconductor device can be taken out of the molds in the resin sealing step more easily. Furthermore, it is possible to stick the solder resist of dry film type on which surface the asperity are formed in the second embodiment onto the insulating layer and the wirings, and then, allow the solder resist to be cured and subsequently, form the asperity on the cured solder resist in the third embodiment. Since the asperity is further formed on the surface of the solder resist, adhesion of the solder resist layer to the molds can be suppressed. Further, the first embodiment, the second embodiment and the third embodiment may be combined. Also in this case, since the asperity is further formed on the surface of the solder resist, adhesion of the solder resist layer to the molds can be suppressed.

What is claimed is:

1. An electronic device comprising:
an insulating layer;
a wiring formed on the insulating layer; and
a solder resist layer formed to cover the insulation layer and the wiring and including particles of an elastomer,
wherein an asperity is formed on a surface of the solder resist layer.

2. The electronic device according to claim 1, wherein the asperity is formed to be a groove shape.

3. The electronic device according to claim 1, wherein a region where the wiring is arranged and a region where the wiring is not arranged exist on the insulating layer, and
the asperity is formed corresponding to a level difference between the region where the wiring is arranged and the region where the wiring is not arranged.

4. The electronic device according to claim 3, wherein a width of the wiring is equal to or larger than an average of a radius of the particles of the elastomer.

5. The electronic device according to claim 3, wherein a dummy wiring being electrically isolated is included in the wiring.

6. The electronic device according to claim 1, wherein a semiconductor element is mounted on the solder resist layer.

7. A manufacturing method of an electronic device comprising:
forming a solder resist layer including particles of an elastomer to cover an insulating layer and a wiring formed on the insulating layer;
mounting a semiconductor element on the solder resist layer;
crimping a mold on a surface of the solder resist layer to cover the semiconductor element;
sealing the semiconductor element by a resin by curing the resin after filling the resin into the gap between the semiconductor element and the mold; and
taking the surface of the solder resist layer and the resin out of the mold after the sealing, wherein an asperity is formed on the surface of the solder resist layer in the forming the solder resist layer.

8. The manufacturing method of the electronic device according to claim 7, wherein the asperity is formed to be a groove shape.

9. The manufacturing method of the electronic device according to claim 7, wherein the forming the solder resist layer comprises:
applying a solder resist including the particle of the elastomer on the insulation layer and the wiring;
curing the solder resist; and
forming the asperity on the surface of the cured solder resist.

10. The manufacturing method of the electronic device according to claim 9, wherein the asperity is formed by a laser irradiation.

11. The manufacturing method of the electronic device according to claim 9, wherein the asperity is formed by applying an abrasive including an abrasive grain.

12. The manufacturing method of the electronic device according to claim 7, wherein the forming the solder resist comprises:
forming a solder resist including the particles of the elastomer on the insulation layer and the wiring; and
curing the solder resist,
wherein the asperity is formed corresponding to a level difference between the region where the wiring is arranged and the region where the wiring is not arranged in the forming the solder resist.

13. The manufacturing method of the electronic device according to claim 12, wherein in the forming the solder resist including the particles of the elastomer, a film thickness of the solder resist is determined such that the asperity is formed corresponding to the level difference by applying the solder resist on the insulating layer.

14. The manufacturing method of the electronic device according to claim 7, wherein the forming the solder resist comprises:
forming a solder resist including the particles of the elastomer on the insulating layer and the wiring; and
curing the solder resist,
wherein the asperity is formed by:
preparing the solder resist having the surface on which the asperity is formed; and
attaching the solder resist to cover the insulating layer and the wiring such that the asperity is faced to a surface side.

15. The manufacturing method of the electronic device according to claim 14, wherein the solder resist is a dry film type, and
the forming the solder resist including the particles of the elastomer comprises:
attaching the solder resist adhered on a support film to cover the insulating layer and the wiring such that the support film is faced to a surface side; and
stripping the support film from the solder resist after the attaching the solder resist adhered on the support film,
wherein an asperity which meshes with the asperity on the surface of the solder resist is formed on a surface of the support film adhering to the solder resist.

16. The manufacturing method of the electronic device according to claim 7, further comprising:
providing the insulating layer on which the wiring is formed before the forming the solder resist layer.

17. The manufacturing method of the electronic device according to claim 7, further comprising:
forming the wiring on the insulating layer before the forming the solder resist layer.
